(19) United States
(12) Patent Application Publication
(10) Pub. No.: US 2024/0039516 A1
(43) Pub. Date: Feb. 1, 2024

(54) MULTILAYER PIEZOELECTRIC SUBSTRATE PACKAGING METHOD FOR STACKING STRUCTURE

(71) Applicant: SKYWORKS SOLUTIONS, INC., Ivine, CA (US)

(72) Inventors: Rei Goto, Osaka-Shi (JP); Atsushi Takano, Kadoma-Shi (JP)

(73) Assignee: SKYWORKS SOLUTIONS, INC., Irvine, CA (US)

(21) Appl. No.: 18/221,122

(22) Filed: Jul. 12, 2023

Related U.S. Application Data
(60) Provisional application No. 63/369,421, filed on Jul. 26, 2022.

(51) Int. Cl. H03H 9/72; H03H 3/08; H03H 9/02; H03H 9/05

(52) U.S. Cl. CPC H03H 9/725; H03H 3/08; H03H 9/02897; H03H 9/02913; H03H 9/0576

(57) ABSTRACT

A multi-layer piezoelectric substrate silicon package comprises a bottom filter including a cap wafer of the bottom filter, and a device wafer of the bottom filter, the cap wafer of the bottom filter and the device wafer of the bottom filter each having a first through silicon via configured to provide an electrical path from a first bottom terminal of the device wafer of the bottom filter to a first top terminal of the cap wafer of the bottom filter.

### CROSS-REFERENCE TO RELATED APPLICATIONS

This application claims priority under 35 U.S.C. § 119(e) to U.S. Provisional Patent Application Ser. No. 63/369,421, titled “MULTILAYER PIEZOELECTRIC SUBSTRATE PACKAGING METHOD FOR STACKING STRUCTURE,” filed Jul. 26, 2022, the entire content of which is incorporated by reference herein for all purposes.

### BACKGROUND

### Technological Field

The disclosure generally relates to radio frequency (RF) electronic systems and, in particular, to acoustic wave devices and methods of manufacturing thereof.

### Description of the Related Technology

Acoustic wave filters can be implemented in RF electronic systems. For instance, filters in a RF front end of a mobile phone can include acoustic wave filters. An acoustic wave filter can filter a RF signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a RF signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

In accordance with one aspect, there is provided a multi-layer piezoelectric substrate (MPS) silicon (SI) package (PKG) comprising a bottom filter including a cap wafer of the bottom filter, and a device wafer of the bottom filter, the cap wafer of the bottom filter and the device wafer of the bottom filter each having a first through silicon via (TSV) configured to provide an electrical path from a first bottom terminal of the device wafer of the bottom filter to a first top terminal of the cap wafer of the bottom filter.

In some embodiments, the bottom filter comprises a surface acoustic wave (SAW) device of the bottom filter or a bulk acoustic wave (BAW) device of the bottom filter arranged between the cap wafer of the bottom filter and the device wafer of the bottom filter.

In some embodiments, the device wafer of the bottom filter comprises a second through silicon via (TSV) configured to provide an electrical path from a second bottom terminal of the device wafer of the bottom filter to the SAW device of the bottom filter or the BAW device of the bottom filter.

In some embodiments, the bottom filter comprises a seal ring arranged between the cap wafer of the bottom filter and the device wafer of the bottom filter.

In some embodiments, the bottom filter comprises a support pillar arranged between the cap wafer of the bottom filter and the device wafer of the bottom filter.

In some embodiments, the bottom filter comprises an electrical connection arranged between the cap wafer of the bottom filter and the device wafer of the bottom filter, the electrical connection configured to electrically connect the first TSV of the cap wafer of the bottom filter and the first TSV device wafer of the bottom filter.

In some embodiments, the MPS SI PKG further comprises a top filter including a cap wafer of the top filter, and a device wafer of the top filter, the device wafer of the top filter having a first TSV of the top filter and a bottom terminal of the device wafer of the top filter configured to provide an electrical path from the first top terminal of the cap wafer of the bottom filter or a first top terminal of the cap wafer of an intermediate filter to a SAW device of the top filter or a BAW device of the top filter arranged between the cap wafer of the top filter and the device wafer of the top filter.

In some embodiments, the top filter further comprises a seal ring arranged between the cap wafer of the top filter and the device wafer of the top filter.

In some embodiments, the top filter further comprises a support pillar arranged between the cap wafer of the top filter and the device wafer of the top filter.

In some embodiments, the MPS SI PKG further comprises an intermediate filter including a cap wafer of the intermediate filter, and a device wafer of the intermediate filter, the cap wafer of the intermediate filter and the device wafer of the intermediate filter each having a first through silicon via (TSV) configured to provide an electrical path from a first bottom terminal of the device wafer of the intermediate filter to a first top terminal of the cap wafer of the intermediate filter.

In accordance with another aspect, there is provided a method of manufacturing a multi-layer piezoelectric substrate (MPS) silicon (SI) package (PKG). The method comprises forming a cap wafer of a bottom filter, bonding the cap wafer of the bottom filter and a device wafer of the bottom filter, and forming a through silicon via (TSV) to provide an electrical path from a first bottom terminal of the device wafer of the bottom filter to a first top terminal of the cap wafer of the bottom filter.

In some embodiments, forming the TSV comprises bonding a support wafer and the device wafer of the bottom filter.

In some embodiments, bonding the support wafer and the device wafer of the bottom filter comprises coating the support wafer with a resist.

In some embodiments, bonding the support wafer and the device wafer of the bottom filter comprises spin coating the resist on the support wafer.

In some embodiments, bonding the support wafer and the device wafer of the bottom filter comprises temporarily bonding the support wafer and the device wafer of the bottom filter.

In some embodiments, forming the TSV comprises grinding the cap wafer of the bottom filter.

In some embodiments, grinding the cap wafer of the bottom filter comprises changing a thickness of the cap wafer of the bottom filter from 110 μm to 90 μm.

In some embodiments, grinding the cap wafer of the bottom filter comprises laser marking of a part number and/or xy-coordinates on the cap wafer of the bottom filter.

In some embodiments, forming the TSV comprises TSV photolithography.

In some embodiments, the TSV photolithography comprises coating the cap wafer of the bottom filter with a TSV resist.

In some embodiments, the TSV photolithography comprises exposure and development.

In some embodiments, forming the TSV comprises dry etching.

In some embodiments, the dry etching comprises TSV resist removal.

In some embodiments, forming the TSV comprises sputtering.

In some embodiments, the sputtering comprises sputtering a titanium (Ti) and copper (Cu) seed layer on the cap wafer of the bottom filter.

In some embodiments, forming the TSV comprises terminal photolithography.

In some embodiments, the terminal photolithography comprises coating the cap wafer of the bottom filter with a terminal resist.

In some embodiments, the terminal photolithography comprises exposure and development.

In some embodiments, forming the TSV comprises forming terminals.

In some embodiments, forming the terminals comprises forming a terminal by Cu via filling plating and, optionally, then SnAg solder plating.

In some embodiments, forming the terminals comprises forming a terminal by Cu via filling plating and then SnAg solder plating.

In some embodiments, the Cu via filling plating has a thickness of 12±2 μm.

In some embodiments, the SnAg solder includes 98% Sn and 2% Ag.

In some embodiments, the plated SnAg solder has a thickness of 23±3 μm.

In some embodiments, forming the TSV comprises terminal resist removal.

In some embodiments, forming the TSV comprises sputter layer etching.

In some embodiments, forming the TSV comprises de-bonding the support wafer from the device wafer of the bottom filter.

In some embodiments, de-bonding the support wafer from the device wafer of the bottom filter comprises thermal and/or mechanical de-bonding.

In accordance with another aspect, there is provided a multiplexer comprising a multi-layer piezoelectric substrate silicon package including a bottom filter having a cap wafer of the bottom filter, and a device wafer of the bottom filter, the cap wafer of the bottom filter and the device wafer of the bottom filter each having a first through silicon via configured to provide an electrical path from a first bottom terminal of the device wafer of the bottom filter to a first top terminal of the cap wafer of the bottom filter.

In accordance with another aspect, there is provided a mobile device comprising a multiplexer including a multi-layer piezoelectric substrate silicon package having a bottom filter having a cap wafer of the bottom filter, and a device wafer of the bottom filter, the cap wafer of the bottom filter and the device wafer of the bottom filter each having a first through silicon via configured to provide an electrical path from a first bottom terminal of the device wafer of the bottom filter to a first top terminal of the cap wafer of the bottom filter.

### BRIEF DESCRIPTION OF THE DRAWINGS

FIG. 1 illustrates a stacked-up temperature compensated surface acoustic wave (TCSAW) device employing a top and a bottom filter on respective support substrates;

FIG. 2 shows an exemplary embodiment of a multilayer piezoelectric substrate (MPS) silicon package having double side external terminals with two stacked SAW filters and tapered through silicon vias;

FIG. 3 shows an exemplary embodiment of a MPS silicon package having double side external terminals with two stacked SAW filters and straight through silicon vias of different dimensions;

FIG. 4 shows an exemplary embodiment of a MPS silicon package having double side external terminals with stacked SAW and BAW filters and tapered through silicon vias;

FIGS. 5A and 5B illustrate the different yields for the devices of FIG. 1 and, e.g., FIG. 2, respectively;

FIG. 6 illustrates a process flow for manufacturing a filter device with a cap and a device wafer and single side terminals;

FIGS. 7A to 7D illustrate a process flow for manufacturing a filter device with a cap and a device wafer and single side terminals including an indication (dashed) of a section to be changed for manufacturing double side terminals (FIG. 7D);

FIGS. 8A and 8B illustrate the process flow replacing the dashed section shown in FIG. 7D enabling the manufacturing of double side terminals;

FIGS. 9A to 9I illustrate an exemplary embodiment of the process flow for manufacturing double side terminals as shown in FIGS. 8A and 8B;

FIG. 10 schematically illustrates an embodiment of a hybrid filter;

FIG. 11 schematically illustrates another embodiment of a hybrid filter;

FIG. 12 schematically illustrates another embodiment of a filter;

FIG. 13 schematically illustrates an embodiment of a multiplexer;

FIG. 14 schematically illustrates another embodiment of a multiplexer;

FIG. 15 shows a MPS SI PKG according to FIG. 2 having printed inductors inside and outside the PKG;

FIG. 16 shows a MPS SI PKG according to FIG. 2 having electrical shields inside and outside the PKG;

FIG. 17 is a schematic diagram of a radio frequency module that includes a surface acoustic wave component according to an embodiment;

FIG. 18 is a schematic diagram of a radio frequency module that includes a resonator component according to an embodiment;

FIG. 19 is a schematic block diagram of a module that includes a power amplifier, a radio frequency switch, and duplexers according to an embodiment;

FIG. 20 is a schematic block diagram of a module that includes an antenna switch and duplexers according to an embodiment;

FIG. 21 is a schematic block diagram of a wireless communication device that includes a filter in accordance with one or more embodiments; and

FIG. 22 is a schematic block diagram of another wireless communication device that includes a filter in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

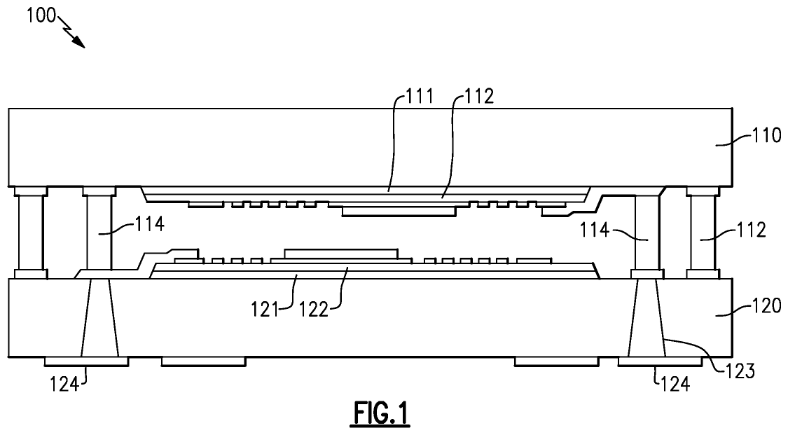

FIG. 1 illustrates a stacked-up temperature compensated surface acoustic wave (TCSAW) device employing a top and a bottom filter on respective support substrates. In the example shown in FIG. 1, each of the top and the bottom filter comprises a functional layer (e.g., of SiO₂), a piezoelectric layer, and an electrical connection. The electrical connection to the top filter and the electrical connection to the bottom filter are disposed between the support substrates within an enclosure formed by a seal ring. Through silicon vias (TSVs) in the support substrate for the bottom filter are provided to connect the top filter to an external electrode. The piezoelectric layer and the functional layer have been removed from the TSVs, seal rings, and metal interconnections to avoid mechanical stress arising from these components.

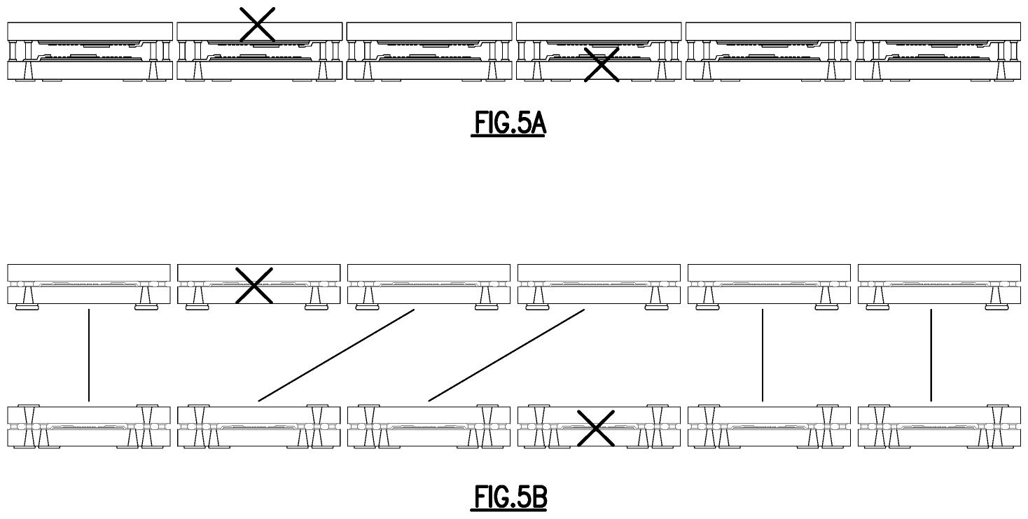

A method of producing stacked-up filters, such as the exemplary stacked-up filter shown in FIG. 1, was proposed to achieve size reduction for acoustic filters. However, due to wafer to wafer bonding, the total yield of the stacked-up filters is determined by the product of the yield for the top filter and the yield for the bottom filter. Hence, assuming a yield of 80% for each filter, a total yield of 64% for the stacked-up filters arises (cf., FIG. 5A).

To increase the yield, a silicon package is proposed with a bottom filter having double side external terminals. A terminal of a top filter is electrically connected to a double sided external terminal of the bottom filter forming, together, a stacked-up structure. Bottom and top filter are separately fabricated and inspected such that the total yield is not the product of the yield for the top filter and the yield for the bottom filter (cf., FIG. 5B).

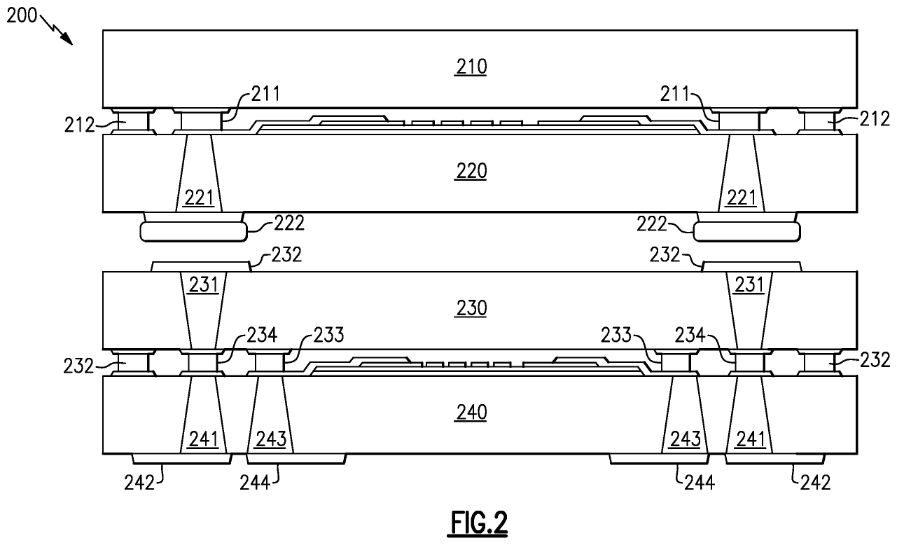

FIGS. 2 to 4 show exemplary embodiments of multilayer piezoelectric substrate (MPS) silicon packages having double side external terminals with examples of same and different filters and examples of TSVs of different shapes and dimensions.

FIG. 2 shows an exemplary embodiment of a MPS silicon package 200 having double side external terminals with two stacked SAW filters and tapered TSVs. The top filter comprises a cap wafer 210 and a device wafer 220. The cap wafer 210 is supported by one or more support pillars 211. The support pillars 211 may, at least in part, define a cavity between the cap wafer 210 and the device wafer 220. The top filter may comprise one or more seal rings 212. The device wafer 220 of the top filter comprises one or more TSVs 221. In the exemplary embodiment, the two TSVs 221 are of a tapered shape in at least one direction. Different shapes are also possible, such as straight and/or tapered, in one or several different, linearly independent directions. The device wafer 220 of the top filter comprises one or more bottom terminals each connected to a respective TSV.

The bottom filter of the MPS silicon package 200 comprises a cap wafer 230 and a device wafer 240. The cap wafer 230 is supported by one or more support pillars 233. The support pillars 233 may, at least in part, define a cavity between the cap wafer 230 and the device wafer 240 of the bottom filter. The bottom filter may comprise one or more seal rings 232. The cap wafer 230 of the bottom filter comprises one or more TSVs 231. In the exemplary embodiment, the two TSVs 231 of the cap wafer 230 of the bottom filter are of a tapered shape in at least one direction. Different shapes are also possible, such as straight and/or tapered, in one or several different, linearly independent directions. Moreover, the shape and the dimensions of TSVs 221 of the top filter and the TSVs 231 of the bottom filter may be different. The cap wafer 230 of the bottom filter may comprise one or more top terminals 232 each connected to a respective TSV 231 of the cap wafer 230. The one or more top terminals 232 of the cap wafer 230 are arranged to enable direct or indirect electrical connection with the one or more bottom terminals of the device wafer 220 of the top filter, in, e.g., a stacked configuration.

The device wafer 240 of the bottom filter comprises one or more TSVs 241 configured for electrical connection with one or more TSVs 231 of the cap wafer 230. The device wafer 240 of the bottom filter comprises one or more bottom terminals 242 each connected to a respective TSV 241 configured for electrical connection with one or more TSVs 231 of the cap wafer 230. The bottom filter has a at least one electrical path from the bottom terminal to top terminal. The at least one electrical path may be formed by TSV 231 and TSV 241 connected via an electrical connection 234.

The device wafer 240 of the bottom filter may comprise one or more TSVs 243 configured for electrical connection into the cavity of the bottom filter. The device wafer 240 of the bottom filter comprises one or more bottom terminals 244 each connected to a respective TSV 243 configured for electrical connection into the cavity of the bottom filter. The one or more support pillars 233 may be electrically connected to a respective TSV 243.

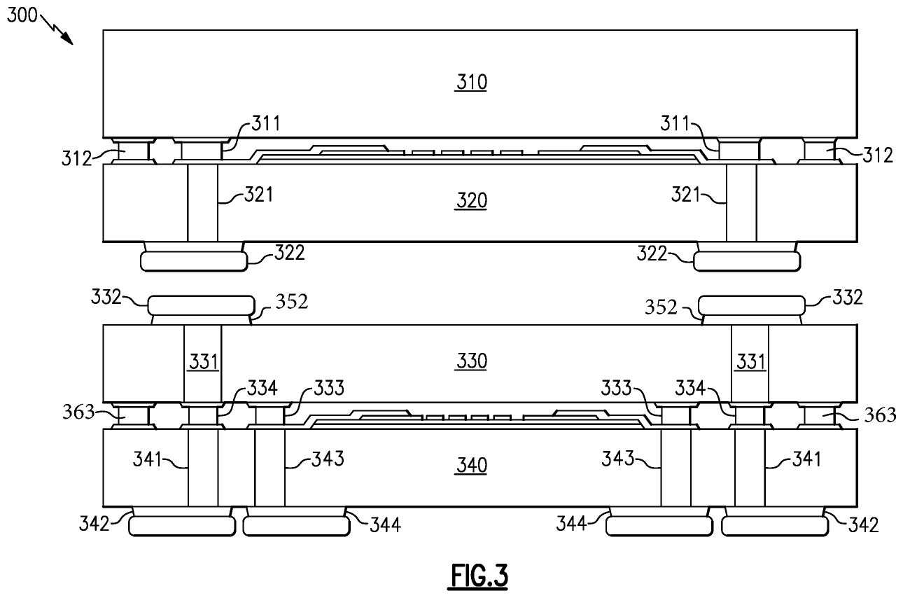

FIG. 3 shows an exemplary embodiment of a MPS silicon package 300 having double side external terminals with two stacked SAW filters and straight TSVs of different dimensions. The top filter comprises a cap wafer 310 and a device wafer 320. The cap wafer 310 may have a thickness of 110 μm. Possible thicknesses may be at minimum 70 μm. The thicknesses may be needed for the molding pressure (800 psi to 1200 psi) and pick-up at visual inspection, taping, and mounting process. The device wafer 320 may have a thickness of 70 μm. Possible thicknesses may be at minimum 70 μm. The thicknesses may be needed for the molding pressure (800 psi to 1200 psi) and probing, pick-up at visual inspection, taping, and mounting process. The cap wafer 310 is supported by one or more support pillars 311. The support pillars 311 may have a width of 50 μm. Possible widths may be at minimum 40 μm. An additional 5 μm may be provided from a TSV pattern edge to a support a pillar edge when considering bonding alignment accuracy. The support pillars 311 may, at least in part, define a cavity between the cap wafer 310 and the device wafer 320. The top filter may comprise one or more seal rings 312. The device wafer 320 of the top filter comprises one or more TSVs 321. In the exemplary embodiment, the two TSVs 321 are of a straight shape in at least one direction. A TSV 321 may have a width of a width of 30 μm. Possible widths may be at minimum 20 μm. When considering the sputtering coverage, a normal sputtering tool may be used to form TSVs 321 with an aspect ratio of about 3. An aspect ratio over 3 may require a special sputtering tool.

The TSVs 321 may have different shapes, such as straight and/or tapered, in one or several different, linearly independent directions.

The device wafer 320 of the top filter comprises one or more bottom terminals 322 each connected to a respective TSV. A Ti/Au layer (unlabeled, but a similar layer labeled 352 on the top of the device wafer 340) may be used at the bottoms of the TSVs 321 between the bottoms of the TSVs 321 and the bottom terminals 322. A TSV edge may be spaced from a bottom Ti/Au layer pattern edge by about 5 μm. In case of a 30 μm TSV, a Ti/Au layer pattern size may be at minimum 40 μm. A thickness of the Ti/Au layer may be 150 nm/700 nm. An etch stop layer may be formed at a bottom of a TSV. The metal material of the etch stop layer may be selected to have a slower plasma etching rate with SF₆/C₄F₈ gas than the Ti/Au layer.

The bottom filter of the MPS silicon package 300 comprises a cap wafer 330 and a device wafer 340. The cap wafer 330 may have a thickness of 90 μm. Possible thicknesses may be at minimum 70 μm. The thicknesses may be needed for the molding pressure (800 psi to 1200 psi) and pick-up at visual inspection, taping, and mounting process. The device wafer 340 may have a thickness of 70 μm. Possible thicknesses may be at minimum 70 μm. The thicknesses may be needed for the molding pressure (800 psi to 1200 psi) and probing, pick-up at visual inspection, taping, and mounting process.

The cap wafer 330 is supported by one or more support pillars 333. The support pillars 333 may have a width of 45 μm. Possible widths may be at minimum 40 μm. An additional 5 μm may be provided from a TSV pattern edge to a support pillar edge when considering bonding alignment accuracy. The support pillars 333 may, at least in part, define a cavity between the cap wafer 330 and the device wafer 340 of the bottom filter. The bottom filter may comprise one or more seal rings 362. The cap wafer 330 of the bottom filter comprises one or more TSVs 331. The TSVs 331 of the cap wafer 330 may have a width of 40 μm. Possible widths may be at minimum 20 μm. When considering the sputtering coverage, a normal sputtering tool may be used to form the TSVs 331 with aspect ratio of about 3. An aspect ratio over 3 may require a special sputtering tool.

In the exemplary embodiment, the two TSVs 331 of the cap wafer 330 of the bottom filter are of a straight shape in at least one direction. Different shapes are also possible, such as straight and/or tapered, in one or several different, linearly independent directions. Moreover, the shape and the dimensions of TSVs 321 of the top filter and the TSVs 331 of the bottom filter may be different. The cap wafer 330 of the bottom filter may comprise one or more top terminals 332 each connected to a respective TSV 331 of the cap wafer 330. The one or more top terminals 332 of the cap wafer 330 are arranged to enable direct or indirect electrical connection with the one or more bottom terminals of the device wafer 320 of the top filter, in, e.g., a stacked configuration.

The device wafer 340 of the bottom filter comprises one or more TSVs 341 configured for electrical connection with one or more TSV 331 of the cap wafer 330. The TSVs 341 configured for electrical connection with one or more TSV 331 of the cap wafer 330 may have a same, or different widths, i.e., smaller or lager with respect to each other. A TSV 341 may have a width of 30 μm. Possible widths may be at minimum 20 μm. When considering the sputtering coverage, a normal sputtering tool may be used until to form the TSVs 341 with an aspect ratio of about 3. An aspect ratio over 3 may require a special sputtering tool.

The device wafer 340 of the bottom filter comprises one or more bottom terminals 342 each connected to a respective TSV 341 configured for electrical connection with one or more TSVs 331 of the cap wafer 330. The bottom filter has a at least one electrical path from the bottom terminal to top terminal. The at least one electrical path may be formed by TSV 331 and TSV 341 connected via an electrical connection 334. The electrical connection 334 may have the same dimensions as a support pillar 333.

The device wafer 340 of the bottom filter may comprise one or more TSVs 343 configured for electrical connection into the cavity of the bottom filter. The device wafer 340 of the bottom filter comprises one or more bottom terminals 344 each connected to a respective TSV 343 configured for electrical connection into the cavity of the bottom filter. The one or more support pillars 333 may be electrically connected to a respective TSV 343.

The bottom terminal 344 may use the same material and the same thickness as bottom terminal 342. Cu: 12 μm+/−2 μm, Solder: 23 μm+/−3 μm.

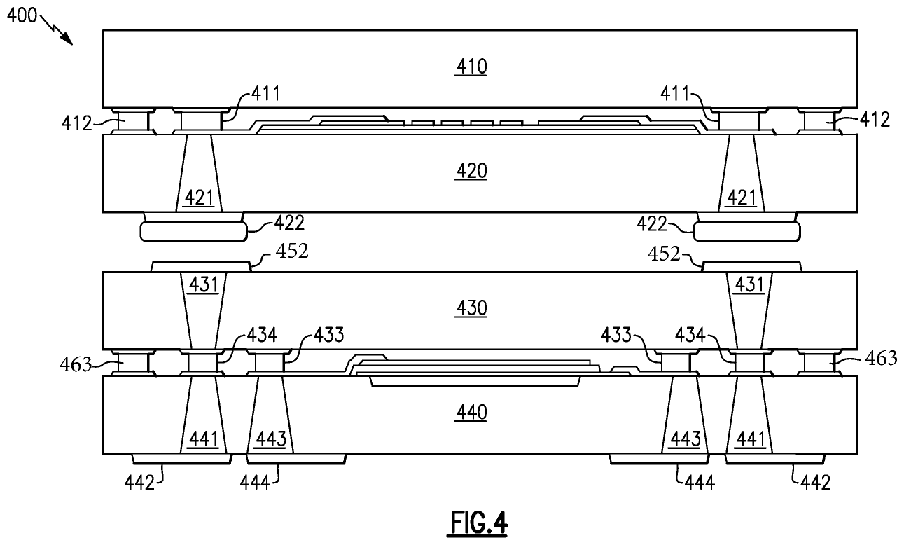

FIG. 4 shows an exemplary embodiment of a MPS silicon package 400 having double side external terminals with stacked SAW and BAW filters and tapered through silicon vias. As shown in the exemplary embodiment, the top filter may be a SAW filter while the bottom filter may be a BAW filter. The exemplary shapes and dimensions of the TSVs, the wafers, the support pillars, the terminals, etc. described in relation to FIG. 2 and FIG. 3 may be adopted. Features of the MPS silicon package 400 corresponding to those of the MPS silicon package 300 are given the same reference numbers used in FIG. 3, except for the leading “3” being replaced with a “4,” i.e., 4XX instead of 3XX. The dimensions of MPS SAW filter and a MPS BAW filter package may be the same.

FIGS. 5A and 5B illustrate the different yields for the devices of FIG. 1 and, e.g., FIG. 2, respectively. In the example shown in FIG. 5A, a defective top filter requires removal of an operational bottom filter, and vice versa. Hence, the wafer to wafer bonding total yield for the stacked device is the product of the yield for the top filter and the yield for the bottom filter. In the example shown in FIG. 5B, the yield for the top filter does not necessarily affect the yield for the bottom filter, and vice versa.

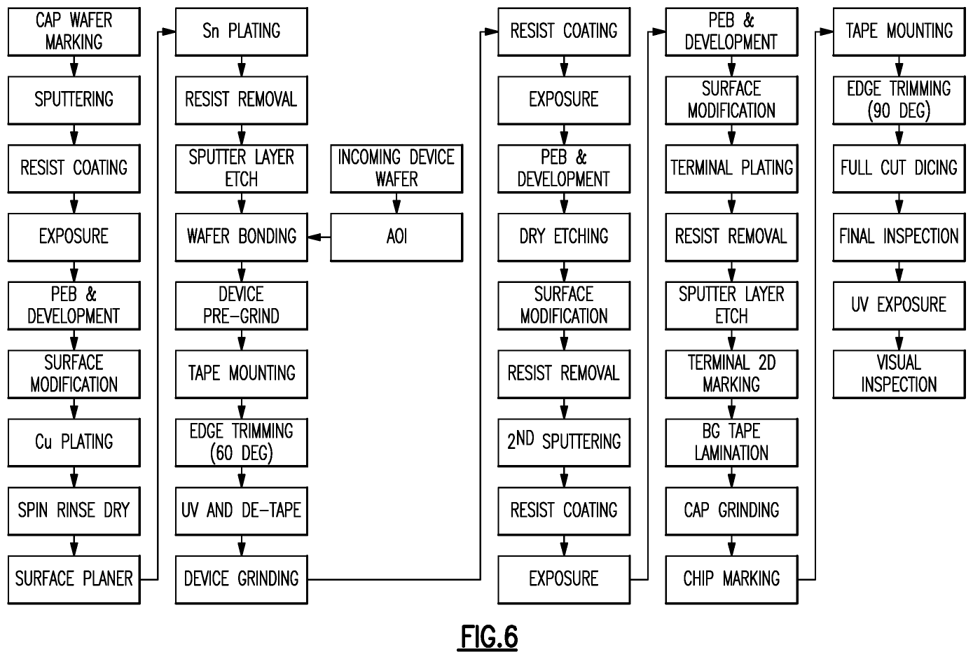

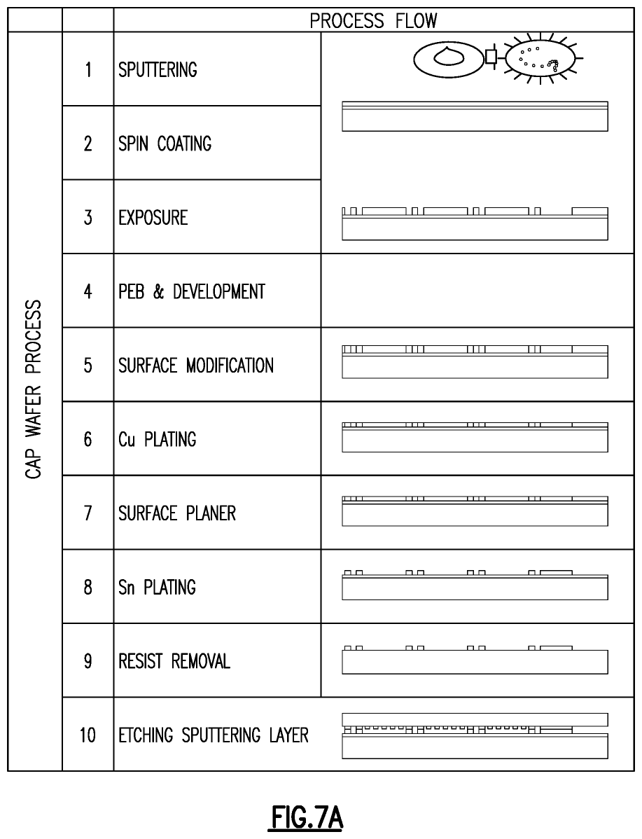

FIG. 6 illustrates a process flow for manufacturing a filter device with a cap and a device wafer and single side terminals connected to single side TSVs.

The process flow in FIG. 6 may comprise cap wafer formation.

Cap wafer formation may comprise cap wafer marking. Cap wafer marking may comprise marking a silicon substrate of 725 μm for traceability using a fully automated laser marking equipment. The marking depth may be less than 1 μm.

Cap wafer formation may comprise sputtering. Sputtering may comprise sputtering a titanium (Ti) and copper (Cu) seed layer on the incoming cap wafer using a fully automated sputtering machine. SiO₂ etch rate may be 5±0.25 μm; Ti thickness may be 0.11±0.017 μm; Cu thickness may be 0.40±0.06 μm.

Cap wafer formation may comprise spin resist coating. Spin resist coating may comprise spin coating a layer of positive resist on top of the seed layer using a fully automated spin coating machine. Resist thickness may be 25±5 μm.

Cap wafer formation may comprise exposure. Exposure may comprise exposing the resist in preparation to create a pattern using an exposure mask and a fully automated exposure equipment.

Cap wafer formation may comprise post exposure bake (PEB) and development, and surface modification. Surface modification may comprise modifying the surface of the photoresist to prepare it for copper (Cu) plating using a fully automated surface modification equipment.

Cap wafer formation may comprise Cu plating. Cu plating may comprise plating of copper to fill in the patterns formed by the photolithography process using fully automated plating equipment. Plating thickness may be 17 to 23 μm.

Cap wafer formation may comprise surface planarization process. The surface planarization process may comprise “fly-cutting” the resist and copper to ensure its flatness using a fully automated surface planarization tool. Total thickness variation may be 1.5 μm.

Cap wafer formation may comprise tin (Sn) plating. Sn plating may comprise plating a layer of tin in preparation for wafer to wafer bonding using fully automated plating equipment. Sn thickness may be 2.30±0.3 μm.

Cap wafer formation may comprise photoresist removal and sputter layer etching. Photoresist removal and sputter layer etching may comprises removing the photoresist and sputter layer(s) chemically using fully automatic batch etching equipment.

Sputter layer etching may be the final step of the cap wafer formation. After sputter layer etching, the cap wafers may be ready for wafer bonding.

The process flow in FIG. 6 may comprise automated optical inspection (AOI) of the incoming device wafer using a fully automated AOI inspection machine

The process flow in FIG. 6 may comprise bonding.

Bonding may comprise wafer bonding. Wafer bonding may comprise wafer bonding of both cap and device wafers using transient liquid phase (TLP) bonding.

Bonding may comprise pre-grinding. Pre-grinding may comprise grinding the device wafer to 230 μm in preparation for scanning acoustic tomography (SAT) inspection and infrared (IR) inspection. After pre-grinding, the total height of the device wafer, the cap wafer, and the structures therebetween may be 970±28 μm.

Bonding may comprise tape mounting. Tape mounting may comprise mounting the pre-ground wafer to a tape in preparation for a 1^{st} edge trimming using a fully automated tape mounter. The tape may be a UV dicing tape.

Bonding may comprise 1^{st} edge trimming. 1^{st} edge trimming may comprise trimming the circular edge of the wafer to eliminate breaks on the edge of the wafer during the grinding of the device wafer using fully automated edge trimming equipment.

Bonding may comprise UV exposure. UV exposure may comprise removing the UV dicing tape using a fully automatic UV exposure equipment.

Bonding may comprise device grinding. Device grinding may comprise grinding the device wafer to its final thickness using fully automatic back grinding equipment. After device wafer grinding, the total height of the device wafer, the cap wafer, and the structures therebetween may be 810±21 μm.

The process flow in FIG. 6 may comprise TSV formation.

TSV formation may comprise spin resist coating. Spin resist coating may comprise spin coating a resist layer for preparation in creating a TSV using a fully automated spin coating machine. Resist thickness may be 5±2 μm.

TSV formation may comprise exposure. Exposure may comprise exposing the resist in preparation to create a pattern using an exposure mask and fully automated exposure equipment.

TSV formation may comprise post exposure bake (PEB) and development of the exposed photoresist.

TSV formation may comprise dry etching. Dry etching may comprise dry etching/creating a through via until reaching the terminal pads of the device wafer. Wafer edges may be protected using a wafer edge protection (WEP) ring

TSV formation may comprise surface modification. Surface modification may comprise cleaning the surface of the resist with “F” fluorine (during a dry etch process), to prepare the wafer for resist removal. Surface modification may be performed using fully automated surface modification equipment.

TSV formation may comprise resist removal. Resist removal may comprise removing the resist layer chemically after surface modification. Resist removal may be performed using fully automated batch resist removal equipment.

TSV formation may comprise 2^{nd} sputtering. The 2^{nd} sputtering may comprise sputtering a Ti and Cu seed layer on the device wafer to prepare for terminal formation. SiO₂ etch rate may be 5±0.25 μm; Ti thickness may be 0.11±0.017 μm; Cu thickness may be 0.70±0.11 μm. The 2^{nd} sputtering may be performed using a fully automated sputtering machine.

The process flow in FIG. 6 may comprise terminal formation.

Terminal formation may comprise spin resist coating. Spin resist coating may comprise spin coating photoresist on the device wafer (e.g., negative photo resist). Spin resist coating may be performed using a fully automated spin coating machine. Resist thickness may be 45±5 μm.

Terminal formation may comprise exposure. Exposure may comprise exposing the resist in preparation to create a pattern. Exposure may be performed using an exposure mask and fully automated exposure equipment.

Terminal formation may comprise post exposure bake (PEB) and development, and surface modification. Surface modification may comprise modifying the surface of the photoresist to prepare it for terminal formation. Surface modification may be performed using fully automated surface modification equipment.

Terminal formation may comprise terminal plating. Terminal plating may comprise forming the terminal by filling the Cu via and then plating SnAg solder. Terminal plating may be performed using fully automated plating equipment.

Terminal formation may comprise resist removal. Resist removal may comprise removing the resist layer chemically after forming the terminal layer. Resist removal may be performed using fully automatic batch resist removal equipment.

Terminal formation may comprise sputter layer etching. Sputter layer etching may comprise removing the sputter layer(s) chemically. Sputter layer etching may be performed using fully automatic batch etching equipment. The terminal height may be 35±5 μm.

Terminal formation may comprise 2D marking. 2D marking may comprise transferring the marking information from the cap wafer to the device wafer as the cap wafer will be grinded. 2D marking may be performed using a fully automatic laser marker equipment.

The process flow in FIG. 6 may comprise back grinding.

Back grinding may comprise back grind tape lamination. Back grinding tape lamination may comprise lamination of a back grind tape to protect the terminals during cap back grinding. Typical height of the back grind tape may be 170 μm.

Back grinding may comprise cap back grinding. Cap back grinding may comprise thinning down the cap to a final thickness. After cap back grinding, the total height of the device wafer, the cap wafer, and the structures therebetween may be 380±13 μm.

Back grinding may comprise laser marking. Laser marking may comprise marking the individual chips for traceability. Laser marking may be performed using fully automatic laser marker equipment.

The process flow in FIG. 6 may comprise dicing and testing. Dicing may comprise tape lamination and peeling (remove the BG tape by exposing and peeling off, then mounting the wafer on a dicing tape; for preparation for 2^{nd} edge trimming and full cut dicing), 2^{nd} edge trimming (trimming off the entire edge seal ring using the other side of the edge trim blade (90 deg)), and full cut dicing (cutting the wafer into individual chips). Testing may comprise final inspection (final electrical testing of the individual chips), UV exposure (exposure of the dicing tape in preparation for visual inspection), and visual inspection (picking up of good chips and placing them in tape and reel).

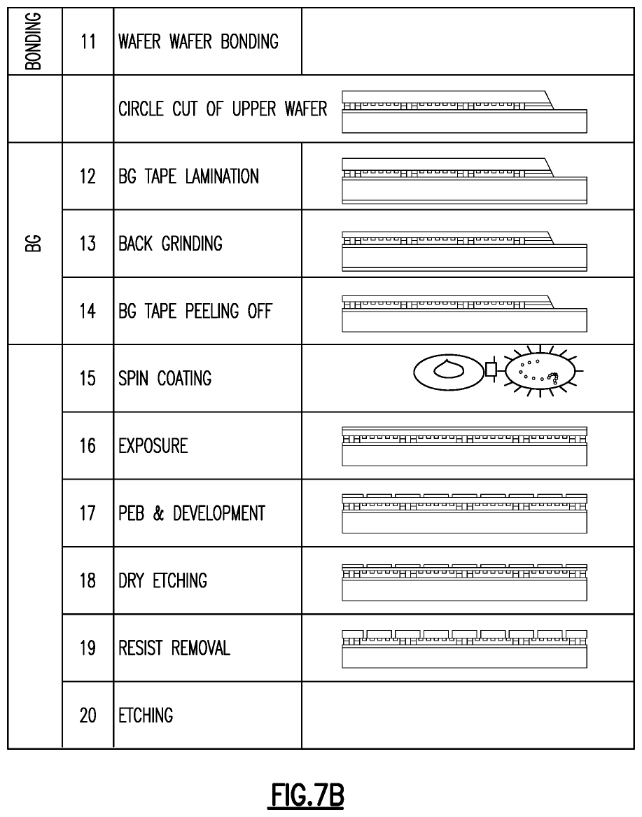

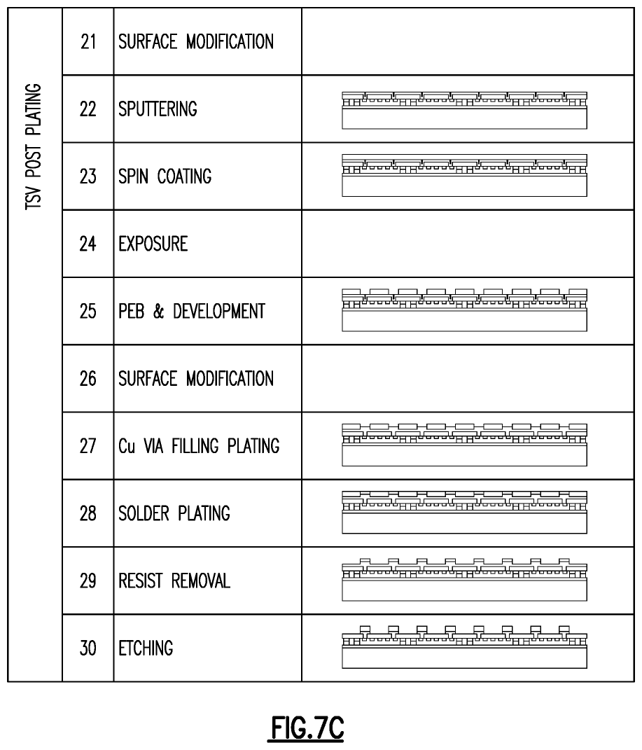

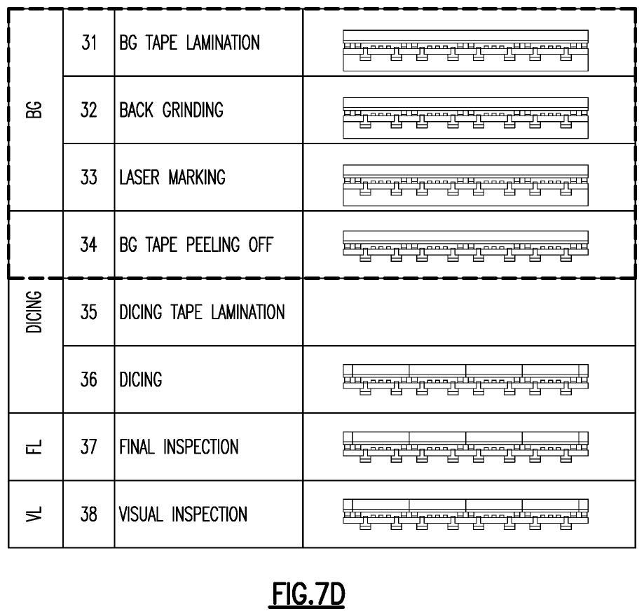

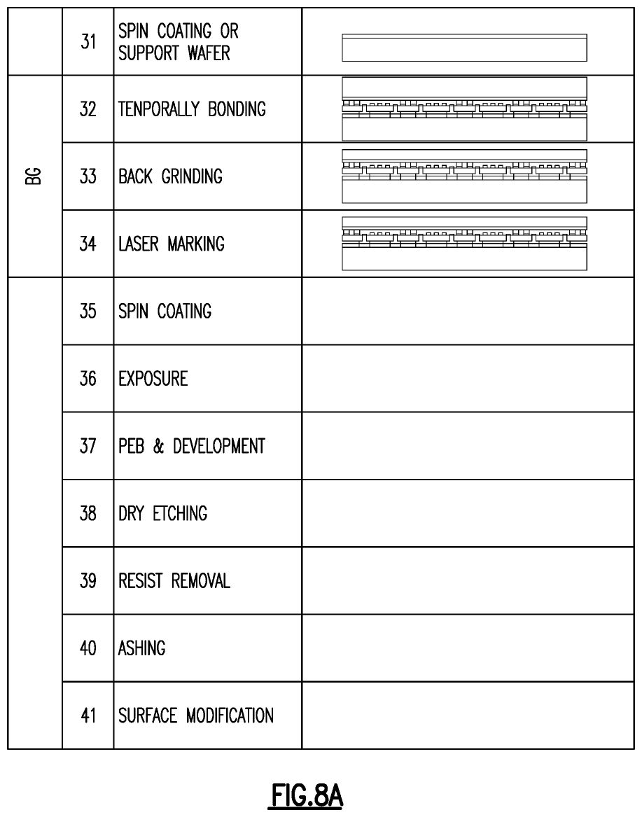

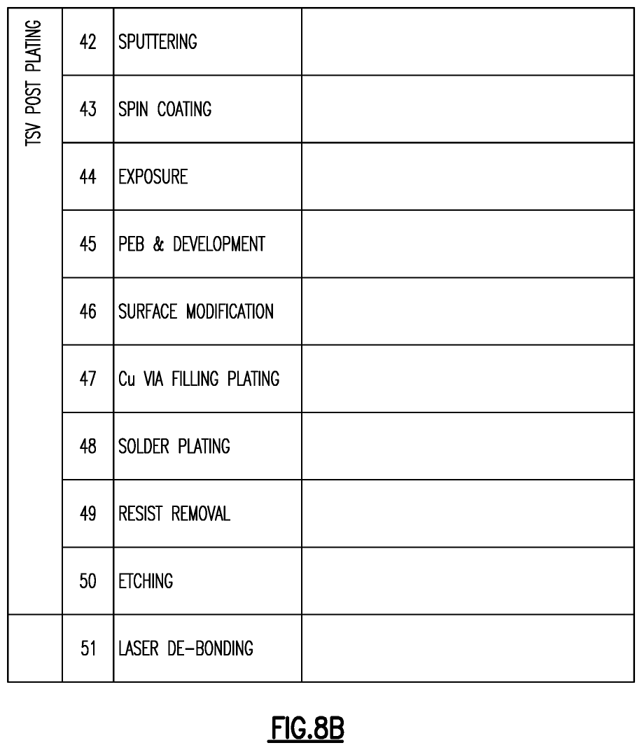

FIGS. 7A to 7D illustrate a process flow for manufacturing a filter device with a cap and a device wafer and single side terminals. As indicated by the dashed box in FIG. 7D, a section of the process flow is changed for manufacturing a filter device with double side terminals. A temporary bonding process and a terminal formation process is added before the cap wafer grinding process, and the process before the mounting on the dicing tape is changed. FIGS. 8A and 8B illustrate the changed process flow replacing the section shown in the dashed box of FIG. 7D. The changed process flow enables the manufacturing of a filter device double side terminals.

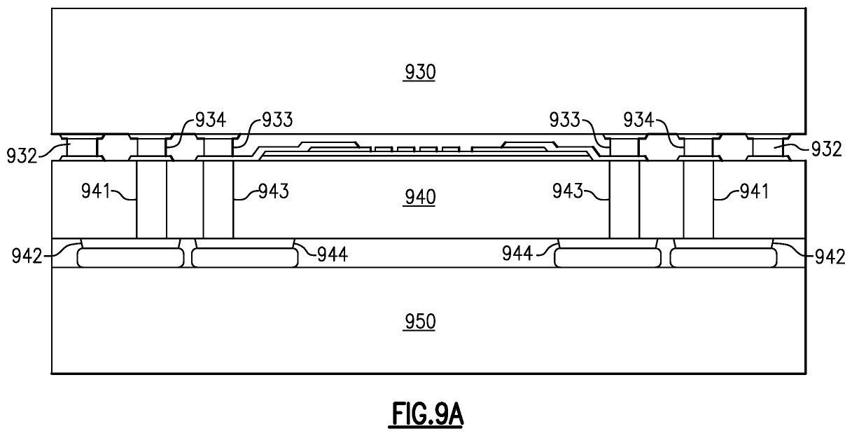

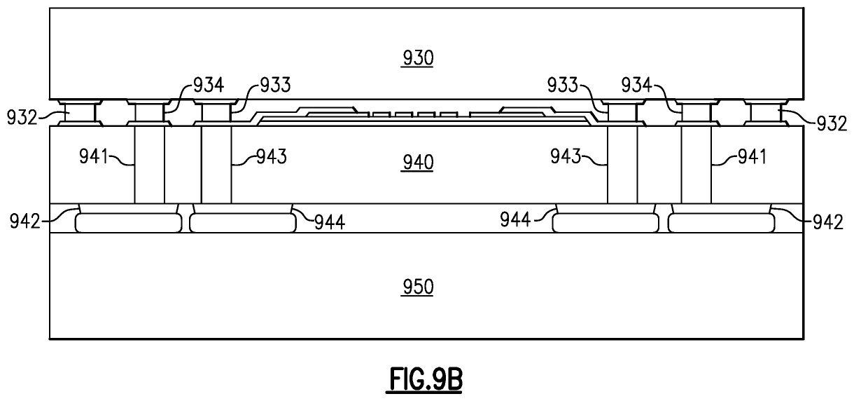

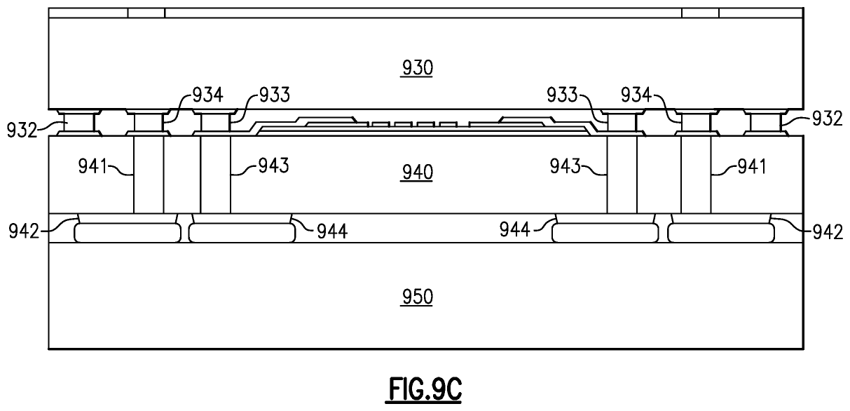

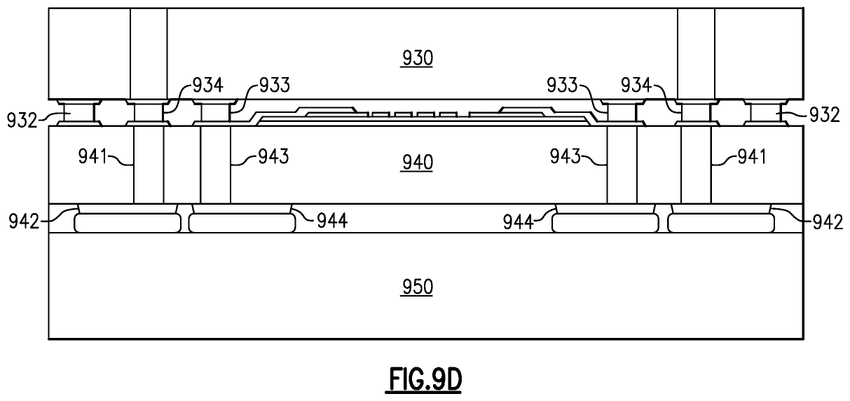

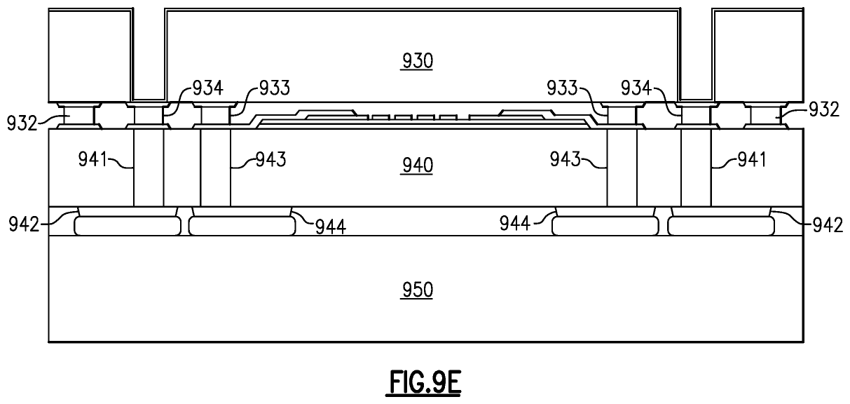

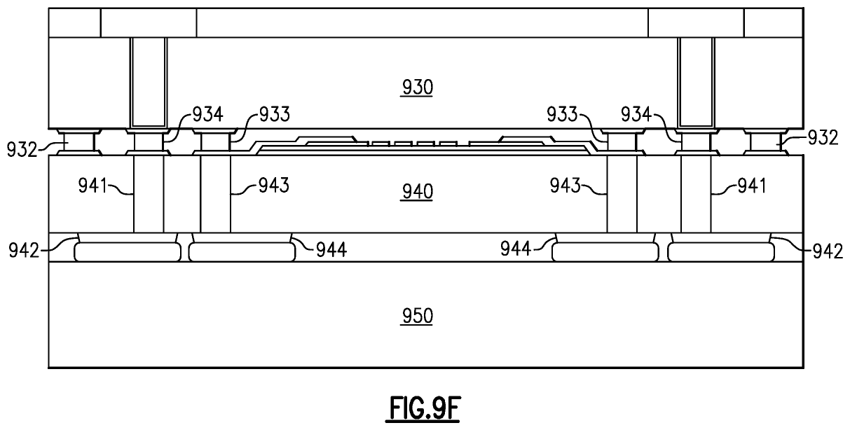

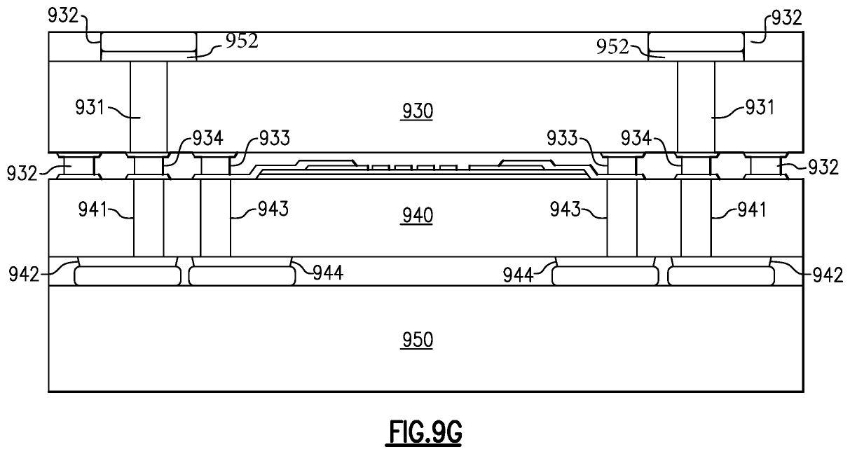

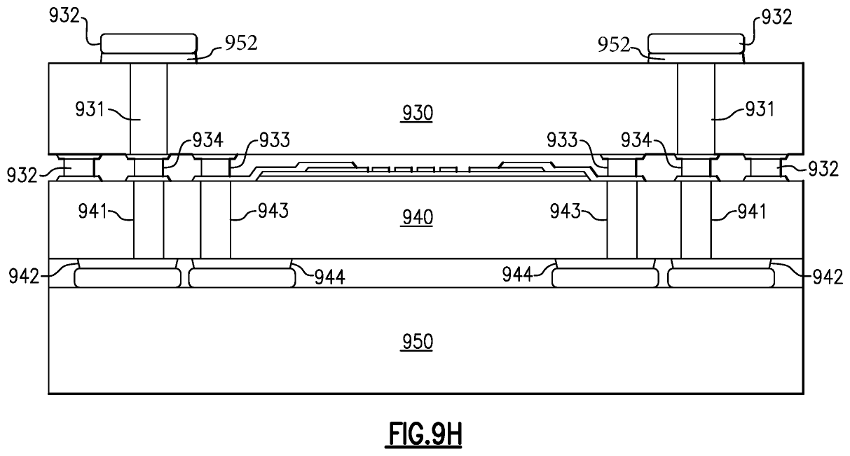

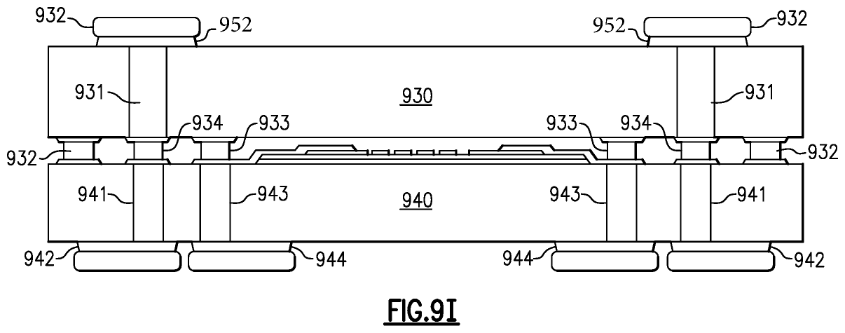

FIGS. 9A to 9I illustrate an exemplary embodiment of the process flow for manufacturing double side terminals shown in FIGS. 8A and 8B. Features of the MPS silicon package in FIGS. 9A to 9I corresponding to those of the MPS silicon package 300 are given the same reference numbers used in FIG. 3, except for the leading “3” being replaced with a “9,” i.e., 9XX instead of 3XX.

The process flow for manufacturing double side terminals may comprise support wafer bonding, cf., FIG. 9A. Support wafer bonding may comprise coating the support wafer 950 with a resist, spin coating for bonding the resist on the support wafer, and temporarily bonding the support wafer on a wafer comprising the terminal that have already been formed. A thickness of the support wafer 950 may be 725 μm.

The process flow for manufacturing double side terminals may comprise cap wafer grinding, cf., FIG. 9B. Cap wafer grinding may comprise changing a cap wafer thickness from, e.g., 110 μm to 90 μm. Cap wafer grinding may comprise laser marking of a part number and/or xy-coordinates on the cap wafer. A marking depth may be less than 1 μm. A marking may be visible in the visible spectrum of light. A marking may be invisible in the infrared.

The process flow for manufacturing double side terminals may comprise TSV photolithography, cf., FIG. 9C. TSV photolithography may comprise resist coating. Resist coating may comprise coating the cap wafer with a resist. The resist may have a thickness of 5±2 μm. TSV photolithography may comprise exposure and development. A TSV pattern may be formed for forming TSVs with widths of, for example, 40 μm.

The process flow for manufacturing double side terminals may comprise a dry etching, cf., FIG. 9D. Dry etching may comprise dry etching the cap wafer until reaching the terminal pads of the cap wafer. Dry etching may comprise a Si dry etching process (Bosch process). Dry etching may comprise inductively coupled plasma (ICP) ashing, an O₂ plasma process to remove the F contaminated resist. Dry etching may comprise resist removal. Resist removal may comprise removing the TSV resist with a resist stripper (wet process).

The process flow for manufacturing double side terminals may comprise a sputtering, cf., FIG. 9E. Sputtering may comprise sputtering a titanium (Ti) and copper (Cu) seed layer on the cap wafer. Sputtering may be performed using a fully automated sputtering machine. The Ti thickness may be 0.11±0.017 μm; the Cu thickness may be 0.9±0.011 μm.

The process flow for manufacturing double side terminals may comprise terminal photolithography, cf., FIG. 9F. Terminal photolithography may comprise resist coating. Resist coating may comprise coating the (sputtered) cap wafer with a resist. The resist may have a thickness of 45±5 μm. Terminal photolithography may comprise exposure and development. The terminal pattern may be formed.

The process flow for manufacturing double side terminals may comprise Terminal formation, cf., FIG. 9G. Terminal formation may comprise terminal plating. Terminal plating may comprise forming the terminal by Cu via filling plating and then SnAg solder plating. Cu via filling plating may have a thickness of 12±2 μm. SnAg solder may have 98% Sn and 2% Ag. The plated SnAg solder may have a thickness of 23±3 μm. Terminal plating may be performed using fully automated plating equipment.

The process flow for manufacturing double side terminals may comprise resist removal and sputter layer etching, cf., FIG. 9H. Resist removal may comprise removing the resist layer with a resist stripper. Resist removal may be performed using fully automatic batch resist removal equipment. Sputter layer etching may comprise removing the sputter layer(s) chemically. Sputter layer etching may be performed using fully automatic batch etching equipment. The terminal height may be 35±5 μm.

The process flow for manufacturing double side terminals may comprise de-bonding, cf., FIG. 9I. De-bonding may comprise de-bonding the support wafer from the device wafer. De-bonding may comprise UV laser scanning from the support wafer side and thermal and/or mechanical de-bonding. De-bonding may comprise cleaning both device wafer and support wafer.

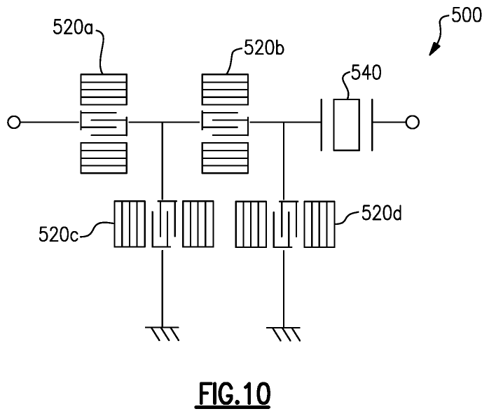

FIG. 10 schematically illustrates an embodiment of a hybrid filter. The hybrid filter includes a plurality of SAW resonators and a BAW resonator. SAW devices can be SAW resonators in acoustic wave filters, such as the hybrid filter 500 of FIG. 10. The hybrid filter 500 includes two SAW resonators 520a and 520b arranged in series with a BAW resonator 540. The hybrid filter 500 also includes two additional SAW resonators 520c and 520d in shunt arrangements. In some embodiments, each of the SAW resonators 520a, 520b, 520c, and 520d may be supported by a single piezoelectric layer, and may include portions of a single temperature compensation layer. The BAW resonator 540 may be supported by this temperature compensation layer, and an electrical connection through the temperature compensation layer between the BAW resonator 540 and the SAW resonators 520b and 520d may be made using a conductive via extending through the temperature compensation layer.

FIG. 11 schematically illustrates another embodiment of a hybrid filter. A SAW device can be a multi-mode SAW filter, such as the hybrid filter 600 of FIG. 11. The filter includes a plurality of BAW resonators and a multi-mode surface acoustic wave filter. The hybrid filter 600 includes two BAW resonators 640a and 640b in series with a multi-mode surface acoustic wave filter 670b, and a third BAW resonator 640c in a shunt arrangement. In such an embodiment, the multi-mode surface acoustic wave filter 670b is included in a hybrid filter with BAW resonators 640a, 640b, and 640c arranged in a ladder topology. The hybrid filter 600 may be used, for example, as a receive filter.

The multi-mode surface acoustic wave (MMS) filter 670b is a type of an acoustic wave filter that includes a plurality of IDT electrodes longitudinally coupled to each other and positioned between acoustic reflectors. These IDT electrodes may be supported by a piezoelectric layer or a multi-layer piezoelectric substrate. The multi-mode surface acoustic wave filter 670b may be temperature compensated by including a temperature compensation layer, such as a silicon dioxide layer, over the IDT electrodes. Some or all of the BAW resonators 640a, 640b, and 640c may be supported by this temperature compensation layer, and a connection between the multi-mode surface acoustic wave filter 670b and the BAW resonator 640b may include a conductive via extending through the temperature compensation layer.

Some MMS filters are referred to as double mode surface acoustic wave (DMS) filters. There may be more than two modes of such DMS filters and/or for other MMS filters. MMS filters can have a relatively wide passband due to a combination of various resonant modes. MMS filters can have a balanced (differential) input and/or a balanced output with proper arrangement of IDTs. MMS filters can achieve a relatively low loss and a relatively good out of band rejection. In certain applications, MMS filters can be receive filters arranged to filter radio frequency signals.

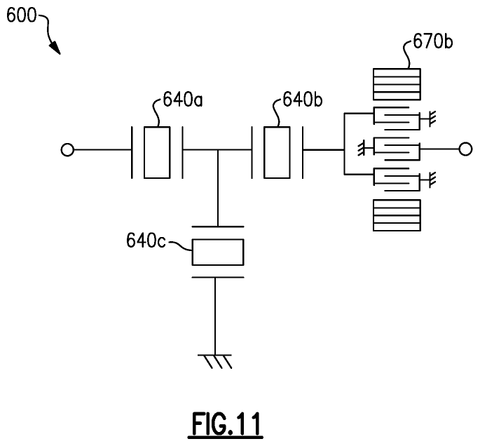

FIG. 12 schematically illustrates another embodiment of a filter. A SAW device can be a delay element, such as the hybrid filter 700 of FIG. 12. The filter includes a plurality of BAW resonators and a cancellation circuit that includes SAW delay element. The filter 700 includes three BAW resonators 740a, 740b, and 740c arranged in series, with two additional BAW resonators 740d and 740e in a shunt arrangement. The filter 700 also includes a SAW cancellation circuit 780 capacitively coupled to the ladder arrangement of BAW resonators 740a, 740b, 740c, 740d, and 740e. The capacitively coupled SAW cancellation circuit 780 may achieve higher rejection of the filter 700, for example, by generating an anti-phase signal to a target signal at a particular frequency.

The SAW cancellation circuit 780 may include an IDT electrode supported by a piezoelectric layer and may also include a portion of a temperature compensation layer overlying the IDT electrodes. At least some of the BAW resonators 740a, 740b, 740c, 740d, and 740e may be supported by the temperature compensation layer, and electrical connections may be made through the temperature compensation layer between the BAW resonators 740a and 740c and the SAW cancellation circuit 780, such as by using a conductive via extending through the temperature compensation layer.

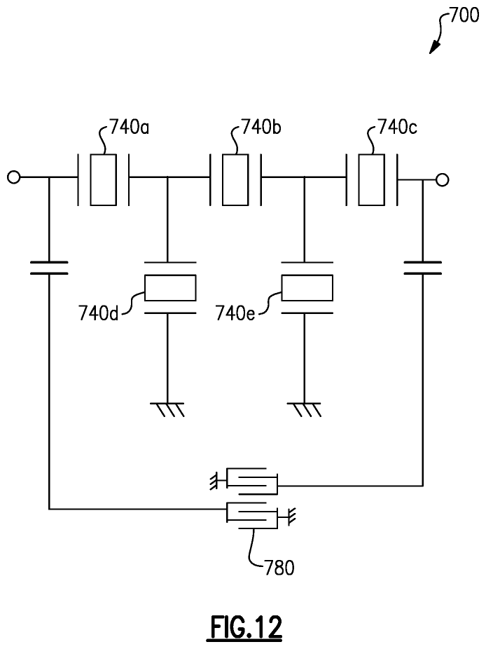

FIG. 13 schematically illustrates an embodiment of a multiplexer. The multiplexer includes a plurality of SAW resonators and a plurality of BAW resonators. In the illustrated embodiment, the multiplexer 800 includes a first filter with three series SAW resonators 820a, 820b, and 820c and two shunt SAW resonators 820d and 820e. In addition, the multiplexer 800 includes a second filter with three series BAW resonators 840a, 840b, and 840c, along with two shunt BAW resonators 840d and 840e.

At least some of the SAW resonators 820a, 820b, 820c, 820d, and 820e may include IDT electrodes supported by a piezoelectric layer and may also include portions of a temperature compensation layer overlying the IDT electrodes. At least some of the BAW resonators 840a, 840b, 840c, 840d, and 840e may be supported by the temperature compensation layer, and electrical connections may be made through the temperature compensation layer between the BAW resonator 840a and the SAW resonator 820c, such as by using a conductive via extending through the temperature compensation layer.

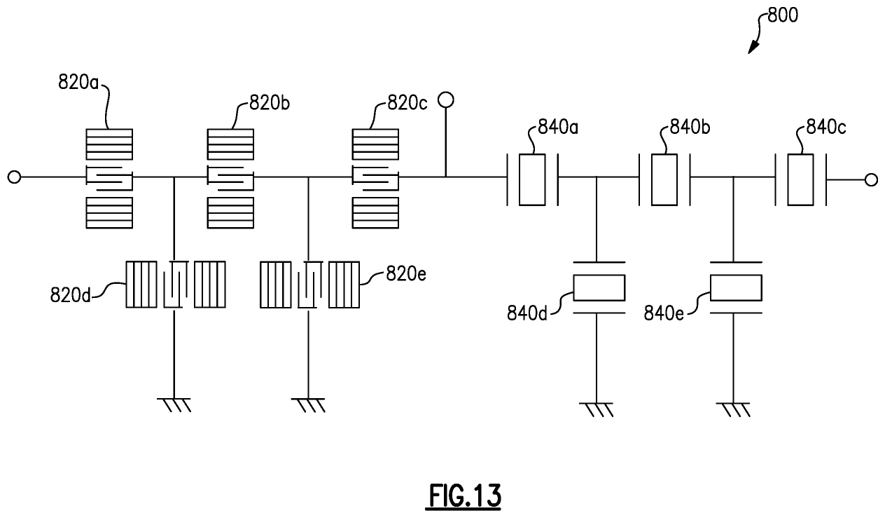

FIG. 14 schematically illustrates another embodiment of a multiplexer. The multiplexer includes a plurality of SAW resonators and a plurality of BAW resonators. The multiplexer 900 is similar to the multiplexer 800 of FIG. 13, except that a BAW resonator 940f has been included in place of a series SAW resonator closest to a common node at which the filters of the multiplexer 900 are coupled to each other. Like the multiplexer 800, at least some of the SAW resonators 920a, 920b, 920d, and 920e, may include IDT electrodes supported by a piezoelectric layer and may also include portions of a temperature compensation layer overlying the IDT electrodes. At least some of the BAW resonators 940a, 940b, 940c, 940d, 940e, and 940f may be supported by the temperature compensation layer. Electrical connection may be made through the temperature compensation layer between the BAW resonator 940f and the SAW resonators 920b and 920e using one or more conductive vias extending through the temperature compensation layer.

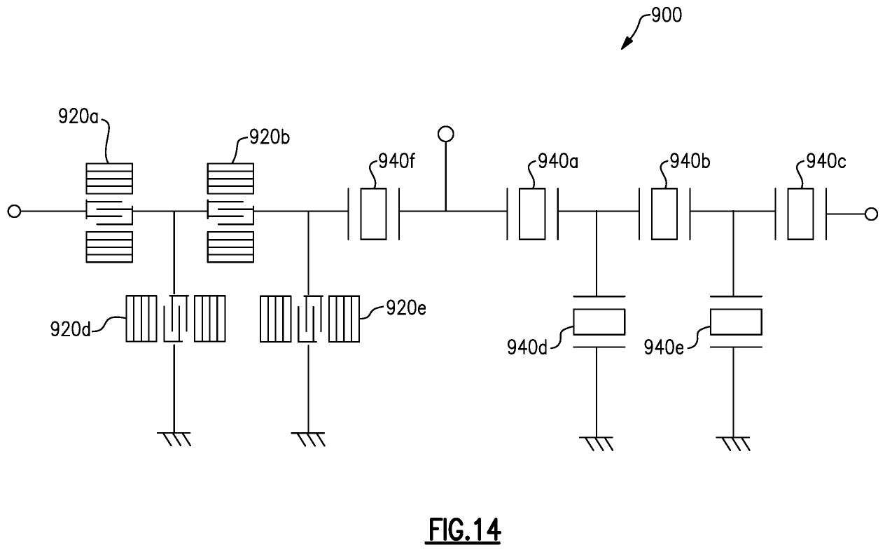

FIG. 15 shows a MPS SI PKG 1500 according to FIG. 2 having printed inductors inside and outside the PKG. Features of the MPS SI PKG 1500 corresponding to those of the MPS silicon package 300 are given the same reference numbers used in FIG. 3, except for the leading “3” being replaced with a “15,” i.e., 15XX instead of 3XX. The stacked MPS SI PKG 1500 may comprise one or more inductors 1560 in addition to a filtering device, such as a SAW or a BAW device. An inductor 1560 may be printed onto the cap wafer 1510 and/or the bottom wafer 1520 of the top filter, inside and/or outside, the top filter. In addition or alternatively, an inductor 1560 may be printed onto the cap wafer 1530 and/or the bottom wafer 1540 of the bottom filter, inside and/or outside, the bottom filter. Printed inductor inside and outside the PKG help to reduce the need to fabricate external inductors in MCM (Multi Chip Module) circuit boards and SMDs (Surface Mount Devices).

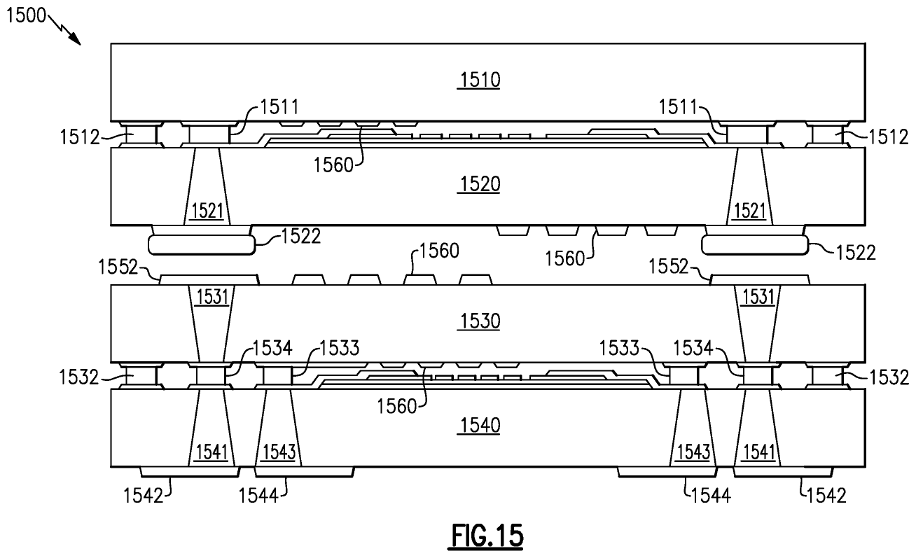

FIG. 16 shows a MPS SI PKG 1600 according to FIG. 2 having electrical shields inside and outside the PKG. Features of the MPS SI PKG 1600 corresponding to those of the MPS silicon package 300 are given the same reference numbers used in FIG. 3, except for the leading “3” being replaced with a “16,” i.e., 16XX instead of 3XX. The stacked MPS SI PKG 1600 may comprise one or more electrical shields 1670. An electrical shield 1670 may be printed onto the cap wafer 1610 and/or the bottom wafer 1620 of the top filter, inside and/or outside, the top filter. In addition or alternatively, an electrical shield 1670 may be printed onto the cap wafer 1630 and/or the bottom wafer 1640 of the bottom filter, inside and/or outside, the bottom filter. An electrical shield is preferably connected to ground. These electrical shields may help to reduce unwanted electrical coupling between the top and bottom filters of the stacked filters. Also, these shields may help to reduce a coupling between filters and other module components.

The embodiments of inductors and electrical shields shown in FIG. 15 and FIG. 16 may be combined with the exemplary embodiments shown in FIG. 2, FIG. 3, or FIG. 4. For instance, a MPS SI PKG according to, e.g., FIG. 2, FIG. 3, or FIG. 4 may comprise a first number of inductors and a second number of electrical shields. Moreover, one or more bottom filters having double side terminals and a top filter may be stacked up to form a stack of three or more filters in a single MPS SI PKG. The cap wafer of the top filter may have neither an inductor nor a shield located on an outer surface of the cap wafer.

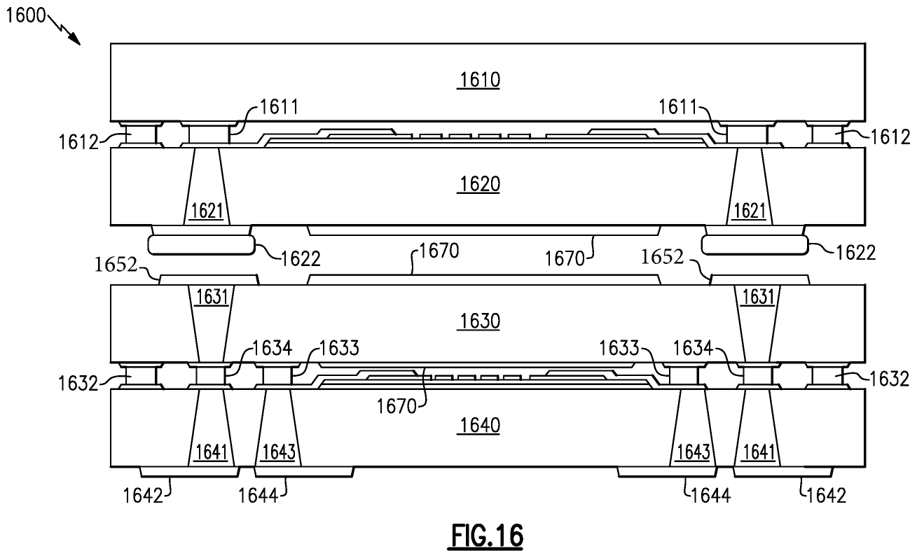

FIG. 17 is a schematic diagram of a radio frequency module 1200 that includes a surface acoustic wave component 1276 according to an embodiment. The illustrated radio frequency module 1200 includes the resonator component 1276 and other circuitry 1277. The resonator component 1276 can include one or more BAW resonators and one or more SAW resonators with any suitable combination of features of the resonator arrangements disclosed herein. The resonator component 1276 can include a die that includes BAW resonators located over SAW resonators.

The resonator component 1276 shown in FIG. 17 includes a filter 1278 and terminals 1279A and 1279B. The filter 1278 includes one or more BAW resonators and one or more SAW resonators. One or more of the BAW resonators can be located over one or more of the SAW resonators in accordance with any suitable principles and advantages disclosed herein. In addition, two or more of the resonators of the filter 1278 can be in a stacked resonator package such as the stacked device structures of FIG. 2, 3, 4, 15, or 16. The terminals 1279A and 1279B can serve, for example, as an input contact and an output contact, and may be in electrical communication with a conductive via extending through at least a piezoelectric layer. The resonator component 1276 and the other circuitry 1277 are on or supported by a common packaging substrate 1280 in FIG. 17. The package substrate 1280 can be a laminate substrate. The terminals 1279A and 1279B can be electrically connected to contacts 1281A and 1281B, respectively, on or supported by the packaging substrate 1280 by way of electrical connectors 1282A and 1282B, respectively. The electrical connectors 1282A and 1282B can be bumps or wire bonds, for example. The other circuitry 1277 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 1200 can include one or more packaging structures to, for example, provide protection and/or facilitate easier handling of the radio frequency module 1200. Such a packaging structure can include an overmold structure formed over the packaging substrate 1280. The overmold structure can encapsulate some or all of the components of the radio frequency module 1200.

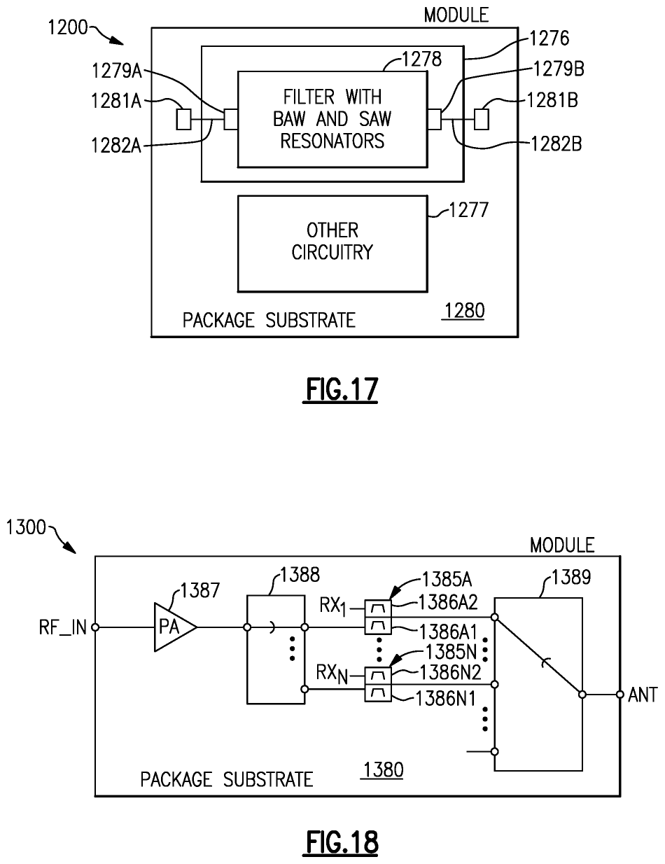

FIG. 18 is a schematic diagram of a radio frequency module 1300 that includes a resonator component according to an embodiment. As illustrated, the radio frequency module 1300 includes duplexers 1385A to 1385N that include respective transmit filters 1386A1 to 1386N1 and respective receive filters 1386A2 to 1386N2, a power amplifier 1387, a select switch 1388, and an antenna switch 1389. The radio frequency module 1300 can include a package that encloses the illustrated elements. The illustrated elements can be disposed on a common packaging substrate 1380. The packaging substrate can be a laminate substrate, for example.

The duplexers 1385A to 1385N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 1386A1 to 1386N1 can include one or more BAW resonators and one or more SAW resonators in accordance with any suitable principles and advantages disclosed herein. Similarly, one or more of the receive filters 1386A2 to 1386N2 can include one or more BAW resonators and one or more SAW resonators in accordance with any suitable principles and advantages disclosed herein. Although FIG. 18 illustrates duplexers, any suitable principles and advantages disclosed herein can be implemented in other multiplexers (e.g., quadplexers, hexaplexers, octoplexers, etc.) and/or in switch-plexers.

The power amplifier 1387 can amplify a radio frequency signal. The illustrated switch 1388 is a multi-throw radio frequency switch. The switch 1388 can electrically couple an output of the power amplifier 1387 to a selected transmit filter of the transmit filters 1386A1 to 1386N1. In some instances, the switch 1388 can electrically connect the output of the power amplifier 1387 to more than one of the transmit filters 1386A1 to 1386N1. The antenna switch 1389 can selectively couple a signal from one or more of the duplexers 1385A to 1385N to an antenna port ANT. The duplexers 1385A to 1385N can be associated with different frequency bands and/or different modes of operation (e.g., different power modes, different signaling modes, etc.).

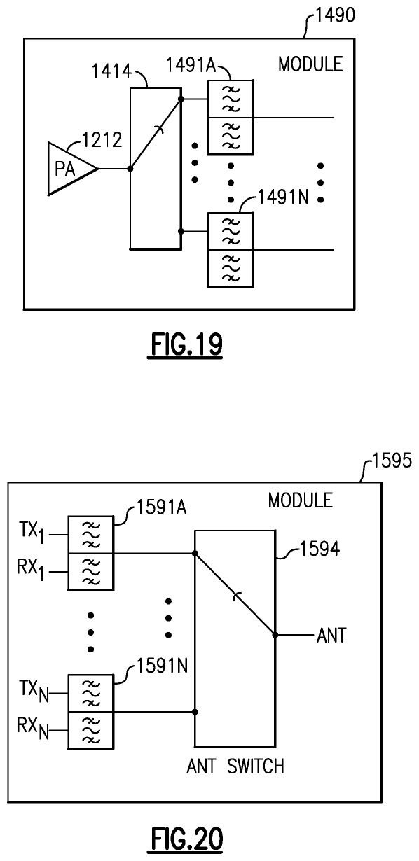

FIG. 19 is a schematic block diagram of a module 1490 that includes a power amplifier 1212, a radio frequency switch 1414, and duplexers 1491A to 1491N in accordance with one or more embodiments. The power amplifier 1212 can amplify a radio frequency signal. The radio frequency switch 1414 can be a multi-throw radio frequency switch. The radio frequency switch 1414 can electrically couple an output of the power amplifier 1212 to a selected transmit filter of the duplexers 1491A to 1491N. One or more filters of the duplexers 1491A to 1491N can include any suitable number of BAW resonators and SAW resonators in accordance with any suitable principles and advantages discussed herein. Any suitable number of duplexers 1491A to 1491N can be implemented.

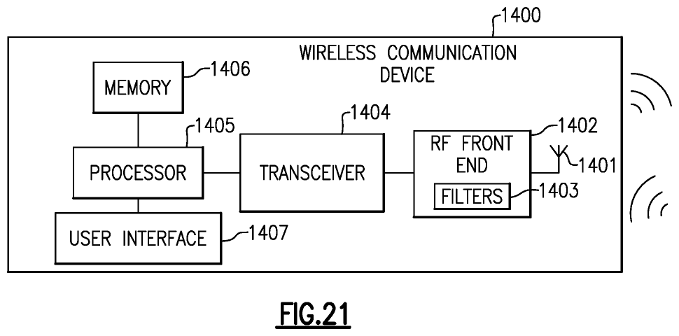

FIG. 20 is a schematic block diagram of a module 1595 that includes duplexers 1591A to 1591N and an antenna switch 1594. One or more filters of the duplexers 1591A to 1591N can include any suitable number of BAW resonators and SAW resonators in accordance with any suitable principles and advantages discussed herein. Any suitable number of duplexers 1591A to 1591N can be implemented. The antenna switch 1594 can have a number of throws corresponding to the number of duplexers 1591A to 1591N. The antenna switch 1594 can electrically couple a selected duplexer to an antenna port of the module 1595.

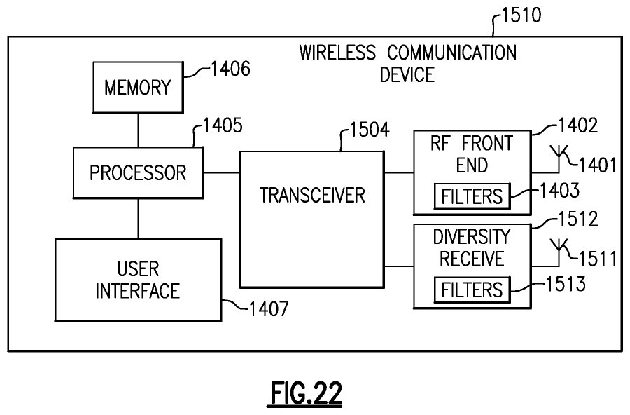

FIG. 21 is a schematic diagram of a wireless communication device 1400 that includes filters 1403 in a radio frequency front end 1402 according to an embodiment. The filters 1403 can include one or more BAW resonators and one or more SAW resonators in accordance with any suitable principles and advantages discussed herein. The wireless communication device 1400 can be any suitable wireless communication device. For instance, a wireless communication device 1400 can be a mobile phone, such as a smart phone. As illustrated, the wireless communication device 1400 includes an antenna 1401, an RF front end 1402, a transceiver 1404, a processor 1405, a memory 1406, and a user interface 1407. The antenna 1401 can transmit RF signals provided by the RF front end 1402. Such RF signals can include carrier aggregation signals. Although not illustrated, the wireless communication device 1400 can include a microphone and a speaker in certain applications.

The RF front end 1402 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 1402 can transmit and receive RF signals associated with any suitable communication standards. The filters 1403 can include BAW resonators and/or SAW resonators of a resonator component that includes any suitable combination of features discussed with reference to any embodiments discussed above.

The transceiver 1404 can provide RF signals to the RF front end 1402 for amplification and/or other processing. The transceiver 1404 can also process an RF signal provided by a low noise amplifier of the RF front end 1402. The transceiver 1404 is in communication with the processor 1405. The processor 1405 can be a baseband processor. The processor 1405 can provide any suitable base band processing functions for the wireless communication device 1400. The memory 1406 can be accessed by the processor 1405. The memory 1406 can store any suitable data for the wireless communication device 1400. The user interface 1407 can be any suitable user interface, such as a display with touch screen capabilities.

FIG. 22 is a schematic diagram of a wireless communication device 1510 that includes filters 1403 in a radio frequency front end 1402 and second filters 1513 in a diversity receive module 1512. The wireless communication device 1510 is like the wireless communication device 1500 of FIG. 21, except that the wireless communication device 1510 also includes diversity receive features. As illustrated in FIG. 22, the wireless communication device 1510 includes a diversity antenna 1511, a diversity module 1512 configured to process signals received by the diversity antenna 1511 and including filters 1513, and a transceiver 1504 in communication with both the radio frequency front end 1402 and the diversity receive module 1512. The filters 1513 can include one or more B AW resonators and one or more SAW resonators that include any suitable combination of features discussed with reference to any embodiments discussed above.

Although embodiments disclosed herein relate to bulk acoustic wave resonators and surface acoustic wave devices, any suitable principles and advantages disclosed herein can be applied to other types of acoustic wave resonators. Any suitable combination of acoustic wave devices may be arranged in a stacked arrangement, with bulk acoustic wave resonators, if present, located in the upper layer of the stacked arrangement.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

An acoustic wave filter including any suitable combination of features disclosed herein can be arranged to filter a radio frequency signal in a fifth generation (5G) New Radio (NR) operating band within Frequency Range 1 (FR1). A filter arranged to filter a radio frequency signal in a 5G NR operating band can include one or more devices of any of the stacked device arrangements disclosed herein. FR1 can be from 410 MHz to 7.125 GHz, for example, as specified in a current 5G NR specification. One or more acoustic wave filters in accordance with any suitable principles and advantages disclosed herein can be arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as die and/or acoustic wave components and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A multi-layer piezoelectric substrate silicon package comprising a bottom filter including a cap wafer of the bottom filter, and a device wafer of the bottom filter, the cap wafer of the bottom filter and the device wafer of the bottom filter each having a first through silicon via configured to provide an electrical path from a first bottom terminal of the device wafer of the bottom filter to a first top terminal of the cap wafer of the bottom filter.

2. The multi-layer piezoelectric substrate silicon package of claim 1 wherein the bottom filter comprises one of a surface acoustic wave (SAW) device of the bottom filter or a bulk acoustic wave (BAW) device of the bottom filter arranged between the cap wafer of the bottom filter and the device wafer of the bottom filter.

3. The multi-layer piezoelectric substrate silicon package of claim 2 wherein the device wafer of the bottom filter comprises a second through silicon via configured to provide an electrical path from a second bottom terminal of the device wafer of the bottom filter to the SAW device of the bottom filter or the BAW device of the bottom filter.

4. The multi-layer piezoelectric substrate silicon package of claim 2 wherein the bottom filter comprises a seal ring arranged between the cap wafer of the bottom filter and the device wafer of the bottom filter.

5. The multi-layer piezoelectric substrate silicon package of claim 2 wherein the bottom filter comprises a support pillar arranged between the cap wafer of the bottom filter and the device wafer of the bottom filter.

6. The multi-layer piezoelectric substrate silicon package of claim 2 wherein the bottom filter comprises an electrical connection arranged between the cap wafer of the bottom filter and the device wafer of the bottom filter, the electrical connection configured to electrically connect the first through silicon via of the cap wafer of the bottom filter and the first through silicon via device wafer of the bottom filter.

7. The multi-layer piezoelectric substrate silicon package of claim 1 further comprising a top filter including a cap wafer of the top filter, and a device wafer of the top filter, the device wafer of the top filter having a first through silicon via of the top filter and a bottom terminal of the device wafer of the top filter configured to provide an electrical path from the first top terminal of the cap wafer of the bottom filter or a first top terminal of the cap wafer of an intermediate filter to a SAW device of the top filter or a BAW device of the top filter arranged between the cap wafer of the top filter and the device wafer of the top filter.

8. The multi-layer piezoelectric substrate silicon package of claim 7 wherein the top filter further comprises a seal ring arranged between the cap wafer of the top filter and the device wafer of the top filter.

9. The multi-layer piezoelectric substrate silicon package of claim 7 wherein the top filter further comprises a support pillar arranged between the cap wafer of the top filter and the device wafer of the top filter.

10. The multi-layer piezoelectric substrate silicon package of claim 1 further comprising an intermediate filter including a cap wafer of the intermediate filter, and a device wafer of the intermediate filter, the cap wafer of the intermediate filter and the device wafer of the intermediate filter each having a first through silicon via configured to provide an electrical path from a first bottom terminal of the device wafer of the intermediate filter to a first top terminal of the cap wafer of the intermediate filter.

11. A method of manufacturing a multi-layer piezoelectric substrate silicon package, the method comprising:
forming a cap wafer of a bottom filter;
bonding the cap wafer of the bottom filter and a device wafer of the bottom filter; and
forming a through silicon via to provide an electrical path from a first bottom terminal of the device wafer of the bottom filter to a first top terminal of the cap wafer of the bottom filter.

12. The method of claim 11 wherein forming the through silicon via comprises bonding a support wafer and the device wafer of the bottom filter.

13. The method of claim 12 wherein bonding the support wafer and the device wafer of the bottom filter comprises coating the support wafer with a resist.

14. The method of claim 13 wherein bonding the support wafer and the device wafer of the bottom filter comprises temporarily bonding the support wafer and the device wafer of the bottom filter.

15. The method of claim 11 wherein forming the through silicon via comprises grinding the cap wafer of the bottom filter.

16. The method of claim 15 wherein grinding the cap wafer of the bottom filter comprises laser marking of a part number and/or xy-coordinates on the cap wafer of the bottom filter.

17. The method of claim 11 wherein forming the through silicon via comprises sputtering a titanium (Ti) and copper (Cu) seed layer on the cap wafer of the bottom filter.

18. The method of claim 11 wherein forming the through silicon via comprises forming terminals.

19. The method of claim 11 wherein forming the through silicon via comprises de-bonding the support wafer from the device wafer of the bottom filter.

20. A mobile device comprising a multiplexer including a multi-layer piezoelectric substrate silicon package having a bottom filter having a cap wafer of the bottom filter, and a device wafer of the bottom filter, the cap wafer of the bottom filter and the device wafer of the bottom filter each having a first through silicon via configured to provide an electrical path from a first bottom terminal of the device wafer of the bottom filter to a first top terminal of the cap wafer of the bottom filter.
